(19) United States
(12) Patent Application Publication
(10) Pub. No.: US 2020/0089033 A1
(43) Pub. Date: Mar. 19, 2020

(54) ARRAY SUBSTRATE, DISPLAY PANEL, AND DISPLAY DEVICE

(71) Applicants: Chongqing HKC Optoelectronics Technology Co., Ltd., Chongqing (CN); HKC Corporation Limited, Shenzhen (CN)

(72) Inventor: Zeyao Li, Chongqing (CN)

(21) Appl. No.: 16/253,219

(22) Filed: Jan. 22, 2019

Related U.S. Application Data
(63) Continuation of application No. PCT/CN2018/111534, filed on Oct. 24, 2018.

(30) Foreign Application Priority Data
Sep. 17, 2018 (CN) 201821517385.9

(51) Int. Cl. G02F 1/1368; G09G 3/36; G02F 1/1335; G02F 1/1345; G02F 1/1362; G02F 1/1343; G02F 1/1337; H01L 27/12

(52) U.S. Cl. CPC G02F 1/1368; G09G 3/3688; G02F 1/133528; G02F 1/13454; G02F 1/136286; G09G 2300/0439; G02F 1/1337; H01L 27/124; G02F 2201/121; G02F 2201/123; G09G 2300/0426; G02F 1/134309

(57) ABSTRACT

The present disclosure discloses an array substrate, a display panel, and display device, the array substrate includes a base and a pixel structure, the pixel structure includes a pixel electrode, a gate electrode, a semiconductor layer, a first electrode, and a second electrode which is defined as surrounding the first electrode.

### CROSS REFERENCE TO RELATED APPLICATIONS

The present application is a Continuation Application of PCT Application No. PCT/CN2018/111534 filed on Oct. 24, 2018, which claims the benefit of Chinese Patent Application No. 201821517385.9 filed on Sep. 17, 2018, the contents of which are incorporated herein by reference in their entirety.

### FIELD

The present disclosure relates to the field of display technology, and in particular, relates to an array substrate, a display panel applying the array substrate, and a display device.

### BACKGROUND

Currently, thin film transistor liquid crystal display (TFT-LCD) occupies a dominant position in the display market, due to its advantages such as high reaction speed, high brightness, and high contrast. The thin film transistor liquid crystal display includes an array substrate, a color substrate, and a liquid crystal layer filled between the two substrates. The liquid crystal display technology in prior art generally employs an array substrate with a bottom gate structure. The on-state current (i.e., charge rate) of such array substrate is proportional to the gap width and inversely proportional to the gap length, i.e., the intensity of the on-state current depends on the width-length ratio of the gap. Referring to FIG. 1, FIG. 1 is a schematic diagram of a pixel cell of a general liquid crystal display panel, the liquid crystal display panel includes a data line 3a, a gate line 4a, a thin film transistor la (TFT), and a pixel electrode 2a. Gap length is generally equal to the distance between a source electrode and a drain electrode, and the gap width is the perimeter of the gap. The width-length ratio of the structure in prior art is relatively small, making the charge rate of the array substrate too small, which affects the display effect of the display panel.

### SUMMARY

The main purpose of the present disclosure is to provide an array substrate, which aims at improvement of the light transmittance of a display panel and improvement of the display effect.

In order to achieve the above object, the array substrate proposed in the present disclosure includes:

a base;

a plurality of gate lines and data lines, overlying the base, the gate lines and the data lines intersecting with each other to form a plurality of pixel regions;

a plurality of pixel structures, each pixel structure including a thin film transistor which overlies the gate line, and a pixel electrode which is defined in the pixel region,

and the thin film transistor includes a gate electrode which electrically connects a gate line, a semiconductor layer which covers the gate electrode, a first electrode and a second electrode which overlies the semiconductor layer and are defined at intervals, the second electrode surrounds the first electrode and electrically connects the data lines, the pixel electrode electrically connects the first electrode.

In one embodiment of the present disclosure, the second electrode is defined in an annular shape, and the first electrode is defined at the center of the second electrode.

In one embodiment of the present disclosure, a gap is formed between the first electrode and the second electrode, the distance between the outer periphery of the first electrode and the inner periphery of the second electrode is a length of the gap, the perimeter of the central line of the gap is a width of the gap, and the width-length ratio of the gap ranges from 8π to 24π.

In an embodiment of the present disclosure, the array substrate also includes a first isolation layer and a second isolation layer, the first isolation layer is defined between the gate electrode and the semiconductor layer, the second isolation layer covers the first electrode and second electrodes, the pixel electrode covers the second isolation layer and electrically connects the first electrode.

In one embodiment of the present disclosure, the second isolation layer is defined with a connecting port, the pixel electrode defines a connecting branch, the connecting branch extends from the edge of the pixel electrode to the connecting port, and abuts against the first electrode through the connecting port.

In one embodiment of the present disclosure, the connecting branch covers the periphery of the connecting port, and extends around the periphery of the connecting port.

In one embodiment of the present disclosure, the pixel electrode has a common electrode, the common electrode is defined crosswise, and forms a plurality of domains by division, a plurality of pixel branches are defined in each domain, the plurality of pixel branches are arranged in parallel intervals, and are defined to form an included angle with the gate line or the data line.

In one embodiment of the present disclosure, the common electrode intersects in a cross shape, the plurality of pixel branches are radially distributed with the intersection of the common electrodes as the center of the circle, and a slot is formed between two adjacent pixel branches.

The present disclosure also provides a display panel, which includes the array substrate, the color substrate, and the liquid crystal layer, as described above.

the color substrate forming a sealed space with the array substrate, the liquid crystal layer being defined in the sealed space.

The present disclosure also provides a display device, which includes the display panel as described above and a backlight module connecting the display panel.

According to the technical scheme of the present disclosure, the array substrate includes a data line and a gate line. The data line and the gate line are defined on a base, and divide the array substrate into a plurality of pixel regions. Each pixel region is defined with a thin film transistor, so that each pixel structure may be controlled independently; and, the thin film transistor includes a second electrode electrically connected with the data line and a first electrode electrically connected with a pixel electrode, thereby realizing transmission of signals from the data line to the pixel electrode. And, the second electrode surrounds the first electrode, so that the gap shape formed by the second electrode and the first electrode is in a closed state without increasing the size of the thin film transistor. Under such situation, the gap width may reach the maximum compared with the shape with openings. Thus, the width-length ratio is significantly increased, and the passage for electron flowing is increased when charging the pixel electrode, which thereby increases the charging rate and the display effect of the array substrate.

### BRIEF DESCRIPTION OF THE DRAWINGS

To illustrate the technical solutions according to the embodiments of the present invention or in the prior art more clearly, the accompanying drawings for describing the embodiments or the prior art are introduced briefly in the following. Apparently, the accompanying drawings in the following description are only about some embodiments of the present invention, and persons of ordinary skill in the art can derive other drawings from the accompanying drawings without creative efforts.

FIG. 1 is a structural diagram of a pixel unit in an embodiment of an array substrate;

FIG. 2 is a partial structural diagram of a pixel unit of an array substrate in an embodiment of the present disclosure;

FIG. 3 is a sectional view taken along the line A-A in FIG. 2;

FIG. 4 is a partial diagram of a pixel cell of an array substrate in another embodiment of the present disclosure.

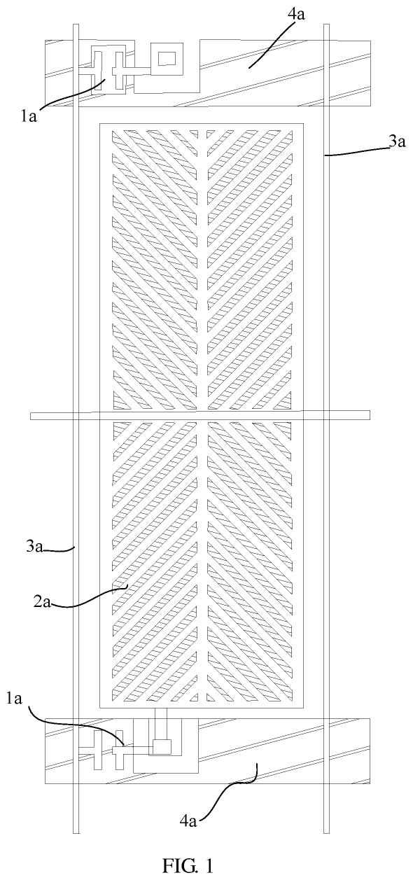

Description of drawing labels

| Label | Name |
|---|---|
| 1a | Thin film transistor |
| 2a | pixel electrode |
| 3a | scanning line |
| 4a | gate line |
| 100 | array substrate |
| 1 | base |
| 2 | gate line |
| 3 | data line |
| 4 | pixel structure |
| 41 | thin film transistor |
| 411 | grid electrode |
| 412 | semiconductor layer |
| 413 | first electrode |
| 414 | second electrode |
| 42 | pixel electrode |
| 421 | connecting branch |
| 422 | common |
| | electrode |
| 423 | pixel branch |
| 424 | slit |
| 43 | the first isolation |
| | layer |
| 44 | the second isolation |
| | layer |
| 441 | connecting port |

The realization, functional features and advantages of the purpose of this disclosure will be further described with reference to the accompanying drawings in conjunction with the embodiments.

### DETAILED DESCRIPTION OF THE EMBODIMENTS

In order to make the purpose, technical scheme and advantages of the.

The technical solutions of the embodiments of the present disclosure will be clearly and completely described in the following with reference to the accompanying drawings. It is obvious that the embodiments to be described are only a part rather than all of the embodiments of the present disclosure. All other embodiments obtained by persons skilled in the art based on the embodiments of the present disclosure without creative efforts shall fall within the protection scope of the present disclosure.

It should be noted that all directional indications (such as up, down, left, right, front, back, etc.) in the embodiments of the present disclosure are only set to explain the relative positional relationship, movement, etc. between the components in a certain posture (as shown in the drawings), and if the specific posture changes, the directional indication changes accordingly.

In this disclosure, unless otherwise expressly specified and defined, the terms “connect”, “fix” and the like shall be understood in a broad sense, for example, “fix” may be a fixed connection, a detachable connection, or an integral body; It can be a mechanical connection or an electrical connection. It can be directly connected or indirectly connected through an intermediate medium. It can be the internal communication of two elements or the interaction relationship between two elements, unless otherwise explicitly defined. For those of ordinary skill in the art, the specific meaning of the above terms in this disclosure can be understood according to the specific circumstances.

In addition, in this disclosure, the descriptions such as “first” and “second” are set for the purpose of description only, and are not to be understood as indicating or implying its relative importance or implicitly indicating the number of indicated technical features. Thus, features defining “first” and “second” may explicitly or implicitly include at least one such feature. In addition, the technical solutions between the various embodiments may be combined with each other, but must be based on what one of ordinary skill in the art can achieve. When the combination of technical solutions is contradictory or impossible to achieve, it should be considered that the combination of such technical solutions does not exist and is not within the scope of protection required by this disclosure.

The present disclosure proposes an array substrate 100.

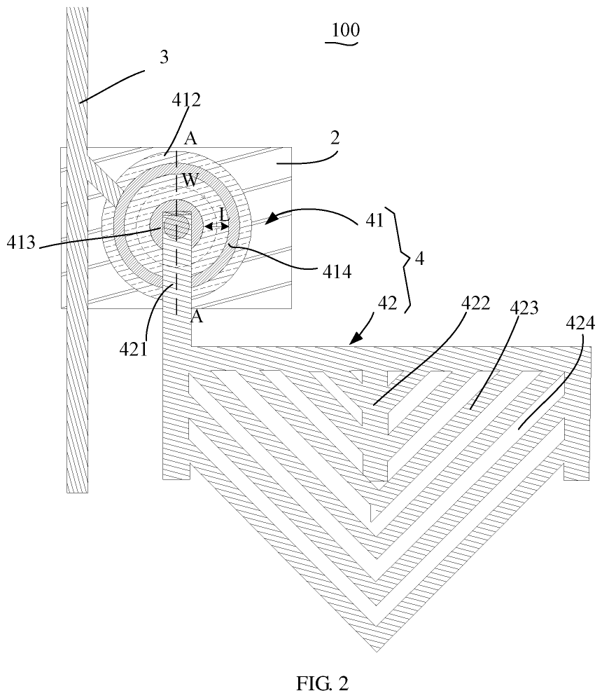

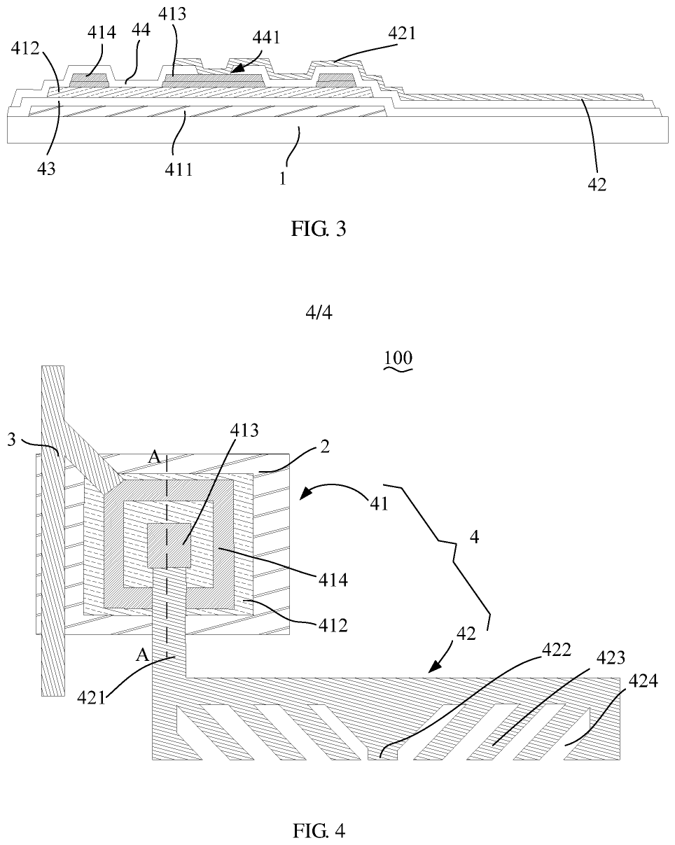

Referring to FIGS. 2 and 3, in an embodiment of the present disclosure, the array substrate 100 includes:

a base 1,

a plurality of gate lines 2 and data lines 3, overlying the base 1, the gate lines 2 and the data lines 3 intersecting with each other to form a plurality of pixel regions;

a plurality of pixel structures 4, each pixel structure 4 including a thin film transistor 41 which overlies the gate line 2, and a pixel electrode 42which is defined in the pixel region,

the thin film transistor 41 includes a gate electrode 411 which is electrically connected with a gate line 2, a semiconductor layer 412 which covers the gate electrode 411, a first electrode 413 and a second electrode 414 which overlies the semiconductor layer 412 and are defined at intervals, the second electrode 414 surrounds the first electrode 413, and electrically connects the data lines 3, the pixel electrode 42 electrically connects the first electrode 413.

In this embodiment, the array substrate 100 is a thin film transistor substrate, that is, a TFT substrate. The base 1 included by the TFT substrate is made of a transparent glass plate, the base allows backlight to pass through it without affection, and offers a fundamental supporter. The base 1 is not conductive, while electrons are needed to drive the movement and arrangement of liquid crystal molecules, thus a conductive portion is defined on the glass supporter for the liquid crystal to control the movement of the liquid crystal. Thereby, the base 1 is sequentially defined with a data line 3, a gate line 2, a thin film transistor 41 and a pixel electrode 42, and each element described above is stacked on the base 1 by the processes of coating, exposing, developing, and etching to ensure the stability of the structure. Both the data line 3 and the gate line 2 are made of opaque non-ferrous metal material. The data line 3 receives the data signal from the data driving circuit and conveys the content to be displayed. The gate line 2 writes the data signal into the pixel electrode 42 and supplies the voltage to turn on and off the thin film transistor 41. The pixel electrode 42 drives the liquid crystal molecules when the circuit is turned on, so that light passes through the content required for display.

When looking down at the array substrate 100, the data line 3 and the gate line 2 form a plurality of pixel areas by intersecting with each other perpendicularly, each pixel unit is defined with a thin film transistor 41 and a pixel electrode 42, and the thin film transistor 41 is defined on the gate line 2, and the pixel electrode 42 is defined in each pixel area. The thin film transistor 41 includes a gate 411, a semiconductor layer 412, a first electrode 413 and a second electrode 414. The first electrode 413 is a drain electrode, the second electrode 414 is a source electrode, or the first electrode 413 is a source electrode and the second electrode 414 is a drain electrode, the specific situation relating to the electric current. For example, under the situation that the first electrode 413 is connected with the pixel electrode 42 and the second electrode 414 is connected with the data line 3, when the thin film transistor 41 is charged, electric current flows from the second electrode 414 to the first electrode 413, then the second electrode 414 is the source electrode and the first electrode 413 is the drain electrode; when the thin film transistor 41 discharges, electric current flows from the first electrode 413 to the second electrode 414, then the first electrode 413 is the source electrode and the second electrode 414 is the drain electrode. In this embodiment, the thin film transistor 41 is charged, the second electrode 414 is defined to be electrically connected with the data line 3 and the first electrode 413 is defined to be electrically connected with the pixel electrode 42. The gate electrode 411 electrically connects the gate line 2 and cooperates with the semiconductor layer 412 to control each pixel structure 4 to turn-on and turn off.

Specifically, a gap is formed between the first electrode 413 and the second electrode 414, the distance between the outer periphery of the first electrode 413 and the inner periphery of the second electrode 414 is a length L of the gap, the perimeter of the central line of the gap is a width W of the gap. By supplying power to the gate 411, the semiconductor layer 412 is made conductive, and then the first electrode 413 and the second electrode 414 are made to communicate with each other, so that the data of the data line 3 is transferred to the pixel electrode 42. Therefore, in the process of charging the thin film transistor 41, the electron flux is inversely proportional to the distance between the first electrode 413 and the second electrode 414, and is directly proportional to the circumference of the channel surrounded by the second electrode 414 and the first electrode 413. i.e. proportional to the ratio w/1 of channel width to length.

According to the technical scheme of the present disclosure, the array substrate 100 includes a data line 3 and a gate line 2. The data line and the gate line are defined on a base 1, and divide the array substrate 100 into a plurality of pixel regions. Each pixel region is defined with a thin film transistor 41, so that each pixel structure 4 may be controlled independently; and, the thin film transistor includes a second electrode 414 electrically connected with the data line 3 and a first electrode 413 electrically connected with a pixel electrode 42, thereby realizing transmission of signals from the data line 3 to the pixel electrode 42. And, the second electrode 414 surrounds the first electrode 413, so that the gap shape formed by the second electrode 414 and the first electrode 413 is in a closed state without increasing the size of the thin film transistor 41. Under such situation, the gap width may reach the maximum compared with the gap shape with openings. Thus, the width-length ratio is significantly increased, and the passage for electron flowing is increased when charging the pixel electrode 42, which thereby increases the charging rate and the display effect of the array substrate 100.

Referring again to FIG. 2, in one embodiment of the present disclosure, the second electrode 414 is defined in an annular shape, and the first electrode 413 is defined at the center of the second electrode 414.

In this embodiment, it is understood that the shapes of the first electrode 413 and the second electrode 414 may be circular, square or other polygonal shapes. The second electrode 414 is defined in an annular shape, and the first electrode 413 is also shaped as a circle, the gap cooperatively formed by the first electrode 413 and the second electrode 414 is shaped as a circle. In one aspect, the width of the gap may be increased, thereby improving the electron flux and the charge rate; In another aspect, the electron flowing in each part of the gap can be made more uniform, thus ensuring the stability of charging.

Referring to FIG. 4, in another embodiment of the present disclosure, the shapes of the second electrode and the first electrode are both square, the gap width in this structure may be maximized without increasing the area of the semiconductor layer 412, thereby further improving the charging rate.

In an embodiment of the present disclosure, and the width-length ratio of the gap ranges from 8π to 24π.

In this embodiment, according to the prior art, the length of the gap may only be controlled to a size in the range of 3 to 6 microns, so the range of the width-length ratio of the gap is set to 8π to 24π without increasing the size of the thin film transistor 41. The charging rate is thereby significantly improved, and insufficient driving force after power failure is avoided, thus ensuring the display stability of the display panel and further improving the display effect of the array substrate 100.

Referring to FIG. 3, in an embodiment of the present disclosure, the array substrate 100 also includes a first isolation layer and a second isolation layer, the first isolation layer 43 is defined between the gate electrode 411 and the semiconductor layer 412, the second isolation layer 44 covers the first electrode 413 and the second electrode 414, the pixel electrode 42 covers the second isolation layer 44 and electrically connects the first electrode 413.

In this embodiment, the first isolation layer 43 and the second isolation layer 44 may be made of a non-conductive resin material, so as to prevent interference between adjacent conductive elements, thereby improving the display effect of the array substrate 100 without affecting the transmission of light. The array substrate 100 has a light-transmitting area that allows light to pass through and a shading area that is opaque. Both the data line 3 and the gate line 2 are made of opaque non-ferrous metal material, so they are defined in the shading area, the thin film transistor 41 is also defined in the shading area. The pixel electrode 42 is transparent conductive metal ITO (Indium Tin Oxide) and does not block backlight, so the pixel electrode 42 is defined in the light-transmitting area, and a second isolation layer 44 is defined between the pixel electrode 42 and the first electrode 413. Therefore, a window is required to be defined for the connection between the two that does not transmit light, the window may be defined in the pixel electrode 42 or be defined above the gate line 2.

Specifically, the second isolation layer 44 is defined with a connecting port 441, the pixel electrode 42 defines a connecting branch 421, the connecting branch 421 extends from the edge of the pixel electrode 42 to the connecting port 441, and abuts against the first electrode 413 through the connecting port 441.

In this embodiment, the connection between the pixel electrode 42 and the first electrode 413 is realized through the connecting port 441, and the connecting port 441 is defined above the gate line 2. Thereby the connection position between the pixel electrode 42 and the first electrode 413 is defined in the shading area. Thus, the light transmission area is enlarged, i.e., the aperture ratio of the pixel structure 4 is increased, thereby effectively increasing the light transmission rate, increasing the amount of liquid crystal molecules imaged, increasing the light transmission rate, and further improving the display quality and brightness.

In one embodiment of the present disclosure, the connecting branch 421 covers the periphery of the connecting port 441, and extends around the periphery of the connecting port 441.

In this embodiment, the connecting branch 421 covers the periphery of the connecting port 441, that is, the portion of the connecting branch 421 defined at the connecting port 441 matches the shape of the connecting port 441, so that the contact area between the connecting branch 421 and the first electrode 413 may be increased, and the contact performance and the stability of power supply may be improved. And the connecting branch 421 extends a certain distance around the periphery of the connecting port 441, so that the cooperation between the connecting branch 421 and the connecting port 441 may be more stable, and the gap between the connecting branch 421 and the connecting port 441 due to assembly may be avoided, thereby ensuring the stability of the connection structure with the first electrode 413. Specifically, the middle portion of the connecting branch 421 may be recessed into the connecting port 441 to form a connecting portion that coincides with the connecting port 441, thereby improving the conductivity of the internal electric current between the connecting branch 421 and the pixel electrode 42, thereby indirectly increasing the charging rate.

Please refer to FIG. 2, in one embodiment of the present disclosure, the pixel electrode 42 has a common electrode 422, the common electrode is defined crosswise, and forms a plurality of domains by division, the plurality of pixel branches 423 are arranged in parallel intervals, the plurality of pixel branches 423 are arranged in parallel intervals, and are defined to form an included angle with the gate line 2 or the data line 3.

In this embodiment, the common electrode 422 of the pixel electrode 42 constitutes its main component, and is made of the same material as the pixel branch 423. A plurality of pixel branches 423 are defined in parallel intervals, and are formed by the common electrode 422 extending around its periphery. That is, the pixel electrode 42 is an integrity, shaped as herringbone, increasing the conductive stability of the pixel electrode 42.

Specifically, the common electrode 422 intersects in a cross shape, the plurality of pixel branches 423 are radially distributed with the intersection of the common electrodes 422 as the center of the circle, and a slit 424 is formed between two adjacent pixel branches 423.

In this embodiment, the two common electrodes 422 are cross-shaped, and one of the common electrodes 422 is parallel to the data line 3 and the other is parallel to the gate line 2. The cross-shaped common electrodes 422 may be divided into four regions, i.e., four domains, the plurality of pixel branches 423 in each domain are radially distributed with the intersection of the common electrodes 422 as the center of the circle. And, the plurality of pixel branches 423 are arranged at 45 degrees to the periphery of the common electrode 422, in the four domains respectively, thereby enlarging the angle of the direction at which liquid crystal molecules move, and achieving higher light transmittance.

Slits 424 are formed between two adjacent pixel branches 423, so the slits 424 are also distributed in parallel intervals, the slits are defined as forming an included angle with a gate line 2 or a data line 3, specifically 45 degrees. The electrodes of the slits 424 are densely arranged. Under the action of an electric field, the slits 424 may drive the liquid crystal molecules to rotate in the inclining direction of the slits 424, so that the liquid crystal molecules may be inclined at 45 degrees. In this condition, the maximum light transmittance may be achieved, and a higher aperture ratio is matched to achieve a high-quality display effect.

The present disclosure also provides a display panel (not shown), which includes the array substrate 100, the color substrate (not shown), and the liquid crystal layer (not shown), as described above. The color substrate 100 forming a sealed space with the array substrate, the liquid crystal layer being defined in the sealed space. The specific structure of the array substrate 100 refers to the above-mentioned embodiments. Since the display panel adopts all the technical solutions of all the above-mentioned embodiments, it has at least all the functions brought about by the technical solutions of the above-mentioned embodiments and will not be described in detail here.

In this embodiment, the display panel may be a liquid crystal display panel. It can be understood that the display panel includes an array substrate 100 and a color filter arranged opposite to each other, and a liquid crystal layer defined between the array substrate 100 and the color substrate. The array substrate 100 and the color substrate form a sealed space via a sealing frame, and the liquid crystal layer is defined in the sealed space. The liquid crystal layer of the present disclosure may have only liquid crystal molecules or may include liquid crystal molecules and phototactic monomers.

The color substrate consists of a glass substrate, a shading layer, a color layer, a protective film and a conductive film. In TFT LCD, the glass substrate needs alkali-free glass. The shading layer is an anti-reflection black matrix made on a glass substrate to prevent light leakage between pixels and increase color contrast. Currently, the shading layer is usually made of metal film and is easy to make. The black matrix corresponds to the shading region of the array substrate 100. The color layer mainly uses the color photoresist as the filter film layer, and its components include high transparency and high heat resistance polymer resin binder, and dye or pigment colorant which makes transparent polymer resin colorful. And the color layer is generally required to have the characteristics such as light resistance, good heat resistance, high color saturation and good penetrability. The purpose of the protective film is to protect the color filter layer and increase the smoothness of the surface. The conductive film is a common electrode and is configured to form a potential difference with the pixel electrode 42 of the array substrate 100, thereby driving liquid crystal molecules.

The display panel is also defined with a lower polarizing plate on the lower surface of the array substrate 100 and an upper polarizing plate on the upper surface of the color substrate. The polarization direction of the lower polarizing plate and the upper polarizing plate is perpendicular. Light firstly passes through the lower polarizing plate to become linearly polarized light, and the polarization direction is consistent with the direction of the lower polarizing plate. When the light passing the liquid crystal layer, due to the refraction by liquid crystal molecules, the polarization direction of the light is turned by 90 degrees via the deflection of the liquid crystal molecules, thereby the light passes the upper polarizing plate perpendicular to the lower polarizing plate, and the display of pictures is realized.

In order to further increase the speed rate of the deflection of the liquid crystal molecule, the array substrate 100 may also be defined with an alignment film, the alignment film covering the pixel electrode 42.

The alignment film is made of polymer plastic. When producing the alignment film, the solution-like material is coated on the surface of the array substrate 100 and then is solidified. A roller of flannel material rolls on the surface to make a certain friction alignment layer, which may generate friction with liquid crystal molecules, thus making the liquid crystal molecules deflect by a predetermined certain angle. Under the action of an electric field, the liquid crystal molecules may deflect more quickly, and the light may pass through quickly, thus ensuring the accuracy and quick of the change of images.

Of course, the color substrate is also defined with an alignment film, which may make the liquid crystal molecule which are close to the color substrate also form a predetermined certain angle. Thus, under the action of an electric field, each pixel may quickly display the corresponding color by further accelerating the deflection speed of the liquid crystal molecules.

When no voltage is applied to the display panel, the liquid crystal molecules defined between the array substrate 100 and the color substrate are freely distributed, and the liquid crystal molecules closer to the alignment film may have a certain deflection angle. When a voltage is applied to the display panel, the liquid crystal molecules are driven by the plurality of slots 424 of the pixel electrode 42 to deflect by the same angle respectively, thereby the liquid crystal molecules deflect more quickly, and the light passes successfully, realizing rapid development. When the voltage is removed, most of the liquid crystal molecules turn to an upright state, and the light may not be passed in this condition.

The present disclosure also provides a display device (not shown) including the display panel described above and a backlight module (not shown) connected with the display panel. The display panel include the array substrate 100 described in the above embodiments. Since the display panel employs all the technical solutions of all the above-mentioned embodiments, it has at least all the functions brought about by the technical solutions of the above-mentioned embodiments and will not be described in detail here.

In this embodiment, the backlight module is defined close to the lower polarizer, and the backlight module is mainly defined to provide a uniform light source with good brightness for the display device. The backlight module generally includes a light source, a light guide sheet, a reflection sheet and an optical film or sheet, and the reflection sheet may be a reflection coating coated on the surface of the light guide plate. The light guide sheet can convert the light source from a point light source to a uniform area light source, and the definition of the reflection sheet may prevent light incident on the light guide plate from being emitted from the side facing away from the exit surface, and reflect the light back into the light guide plate, thus preventing the waste of light energy and effectively improving the utilization rate of light. The backlight provided by the backlight module described above may enable the display device to have a better display effect.

The above is only the preferred embodiment of the present disclosure and is not therefore limiting the scope of the patent disclosure. Any equivalent structural change made under the inventive concept of the present disclosure using the contents of the present disclosure specification and drawings, or directly/indirectly applied in other related technical fields, is included in the scope of the patent protection of the present disclosure.

What is claimed is:

1. An array substrate, comprising:
a base;
a plurality of gate lines and data lines, overlying the base, the gate lines and the data lines intersecting with each other to form a plurality of pixel regions;
a plurality of pixel structures, each pixel structure comprising a thin film transistor which overlies the gate line, and a pixel electrode which is defined in the pixel region; and
the thin film transistor comprising a gate electrode which electrically connects a gate line, a semiconductor layer which covers the gate electrode, a first electrode and a second electrode which overlies the semiconductor layer and are interval defined, the second electrode surrounding the first electrode, the second electrode electrically connecting the data line, and the pixel electrode electrically connecting the first electrode.

2. The array substrate according to claim 1, wherein the second electrode is defined in an annular shape, and the first electrode is defined at the center of the second electrode.

3. The array substrate according to claim 2, wherein a gap is formed between the first electrode and the second electrode, the distance between the outer periphery of the first electrode and the inner periphery of the second electrode is the length of the gap, the perimeter of the central line of the gap is the width of the gap, and the width-length ratio of the gap ranges from 8 π to 24 π.

4. The array substrate according to claim 2, wherein the shapes of the second electrode and the first electrode are both square.

5. The array substrate according to claim 1, wherein the array substrate further comprises a first isolation layer and a second isolation layer, the first isolation layer is defined between the gate electrode and the semiconductor layer, the second isolation layer covers the first electrode and the second electrode, the pixel electrode covers the second isolation layer and electrically connects the first electrode; the second electrode is defined in an annular shape, and the first electrode is defined at the center of the second electrode.

6. The array substrate according to claim 1, wherein the array substrate further comprises a first isolation layer and a second isolation layer, the first isolation layer is defined between the gate electrode and the semiconductor layer, the second isolation layer covers the first electrode and the second electrode, the pixel electrode covers the second isolation layer and electrically connects the first electrode.

7. The array substrate according to claim 6, wherein the second isolation layer defines a connecting port, the pixel electrode defines a connecting branch, the connecting branch extends from the edge of the pixel electrode to the connecting port, and passes through the connecting port to abut against the first electrode.

8. The array substrate according to claim 7, wherein the connecting branch covers the periphery of the connecting port, and extends around from the periphery of the connecting port.

9. The array substrate according to claim 8, wherein the middle part of the connecting branch recesses towards the connecting port to form a connecting portion, and the connecting portion matches with the connecting port.

10. The array substrate according to claim 1, wherein the pixel electrode comprises crosswise defined common electrodes, and a plurality of domains divided by the common electrodes, a plurality of pixel branches are defined in each domain, the plurality of pixel branches are arranged in parallel and interval, and are defined to form an included angle with the gate line or the data line; the second electrode is defined in an annular shape, and the first electrode is defined at the center of the second electrode.

11. The array substrate according to claim 10, wherein the shapes of the second electrode and the first electrode are both square.

12. The array substrate according to claim 1, wherein the pixel electrode comprises crosswise defined common electrodes, and a plurality of domains divided by the common electrodes, a plurality of pixel branches are defined in each domain, the plurality of pixel branches are arranged in parallel and interval, and are defined to form an included angle with the gate line or the data line.

13. The array substrate according to claim 12, wherein the pixel electrode is an integrated structure.

14. The array substrate according to claim 1, wherein the pixel electrode comprises crosswise defined common electrodes, and a plurality of domains divided by the common electrodes, a plurality of pixel branches are defined in each domain, the plurality of pixel branches are arranged in parallel and interval, and are defined to form an included angle of 45 degrees with the gate line or the data line.

15. The array substrate according to claim 14, wherein the common electrodes intersects to present a cross shape, the plurality of pixel branches are radially distributed with the intersection of the common electrodes as a center, and a slit is formed between two adjacent pixel branches.

16. A display panel, comprising: an array substrate, a color substrate, and a liquid crystal layer, the color substrate and the array substrate cooperatively forming a sealed space, the liquid crystal layer being defined in the sealed space,
the array substrate comprising: a base;
a plurality of gate lines and data lines, overlying the base, the gate lines and the data lines intersecting with each other to form a plurality of pixel regions;
a plurality of pixel structures, each pixel structure comprising a thin film transistor which overlies the gate line, and a pixel electrode which is defined in the pixel region;
and the thin film transistor comprising a gate electrode which electrically connects a gate line, a semiconductor layer which covers the gate electrode, a first electrode and a second electrode which overlies the semiconductor layer and are interval defined, the second electrode surrounding the first electrode and electrically connecting the data lines, the pixel electrode electrically connecting the first electrode.

17. The display panel according to claim 16, wherein the second electrode is defined in an annular shape, and the first electrode is defined at the center of the second electrode.

18. The display panel according to claim 16, wherein the array substrate further comprises an alignment film, the alignment film covers the pixel electrode.

19. The display panel according to claim 16, wherein the display panel further comprises a lower polarizer and an upper polarizer, the lower polarizer is defined on a lower surface of the array substrate, the upper polarizer is defined on an upper surface of the color substrate.

20. A display device, comprising: a display panel, and a backlight module connecting the display panel, the display panel comprising an array substrate, a color substrate, and a liquid crystal layer, the color substrate and the array substrate cooperatively forming a sealed space, the liquid crystal layer being defined in the sealed space, the array substrate comprising: a base;
a plurality of gate lines and data lines, overlying the base, the gate lines and the data lines intersecting with each other to form a plurality of pixel regions;
a plurality of pixel structures, each pixel structure comprising a thin film transistor which overlies the gate line, and a pixel electrode which is defined in the pixel region,
and the thin film transistor comprising a gate electrode which electrically connects a gate line, a semiconductor layer which covers the gate electrode, a first electrode and a second electrode which overlies the semiconductor layer and are interval defined, the second electrode surrounding the first electrode and electrically connecting the data lines, the pixel electrode electrically connecting the first electrode.
